(19) United States
(12) Patent Application Publication
(10) Pub. No.: US 2022/0013455 A1
(43) Pub. Date: Jan. 13, 2022

(54) WIRING SUBSTRATE AND METHOD FOR MANUFACTURING WIRING SUBSTRATE

(71) Applicant: IBIDEN CO., LTD., Ogaki (JP)

(72) Inventors: Isao OHNO, Ogaki (JP); Tomoya DAIZO, Ogaki (JP); Yoji SAWADA, Ogaki (JP); Kazuhiko KURANOBU, Ogaki (JP)

(73) Assignee: IBIDEN CO., LTD., Ogaki (JP)

(21) Appl. No.: 17/361,460

(22) Filed: Jun. 29, 2021

(30) Foreign Application Priority Data
Jul. 9, 2020 (JP) 2020-118812

(51) Int. Cl. H01L 23/522; H01L 23/00; H01L 21/768

(52) U.S. Cl. CPC H01L 23/5226; H01L 21/76877; H01L 21/76802; H01L 24/14

(57) ABSTRACT

A wiring substrate includes a resin insulating layer, a via conductor formed in the resin insulating layer such that the via conductor is penetrating through the resin insulating layer, a conductor pad formed on the resin insulating layer and connected to the via conductor, a coating insulating layer formed on the resin insulating layer such that the coating insulating layer is covering the conductor pad, and a metal post formed on the conductor pad and protruding from the coating insulating layer. The via conductor is formed such that the via conductor is increased in diameter toward the conductor pad, and the metal post is formed such that the metal post is increased in diameter toward the conductor pad.

### CROSS-REFERENCE TO RELATED APPLICATIONS

The present application is based upon and claims the benefit of priority to Japanese Patent Application No. 2020-118812, filed Jul. 9, 2020, the entire contents of which are incorporated herein by reference.

### BACKGROUND OF THE INVENTION

### Field of the Invention

The present invention relates to a wiring substrate and a method for manufacturing the wiring substrate.

### Description of Background Art

Japanese Patent Application Laid-Open Publication No. 2010-129996 describes a wiring substrate having a metal post formed on a connection pad. The metal post protrudes upward from a solder resist layer that covers the connection pad. A portion of the metal post covered by the solder resist layer has a tapered shape that is reduced in width toward the connection pad side. The entire contents of this publication are incorporated herein by reference.

### SUMMARY OF THE INVENTION

According to one aspect of the present invention, a wiring substrate includes a resin insulating layer, a via conductor formed in the resin insulating layer such that the via conductor is penetrating through the resin insulating layer, a conductor pad formed on the resin insulating layer and connected to the via conductor, a coating insulating layer formed on the resin insulating layer such that the coating insulating layer is covering the conductor pad, and a metal post formed on the conductor pad and protruding from the coating insulating layer. The via conductor is formed such that the via conductor is increased in diameter toward the conductor pad, and the metal post is formed such that the metal post is increased in diameter toward the conductor pad.

According to another aspect of the present invention, a method for manufacturing a wiring substrate includes preparing a laminate including a conductor layer and a resin insulating layer laminated on the conductor layer, forming a hole in the resin insulating layer such that the hole is connected to the conductor layer and is increased in diameter from a lower side at the conductor layer toward an upper side of the hole, forming a plating resist on the resin insulating layer such that the plating resist has a pad opening connected to the hole, filling the hole and the pad opening with a conductor such that a via conductor is formed in the hole and that a conductor pad is formed in the pad opening, forming a resist layer on the conductor pad such that the resist layer has a post opening connected to the conductor pad and that the post opening is increased in diameter from an upper side toward a lower side of the post opening at the conductor pad, and filling the post opening with a conductor such that a metal post is formed in the post opening.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view partially illustrating an example of a wiring substrate according to an embodiment of the present invention;

FIG. 2 is a partial enlarged cross-sectional view of the wiring substrate of FIG. 1;

FIG. 3 is a cross-sectional view illustrating a different example of the wiring substrate illustrated in FIG. 2;

FIG. 4A is a cross-sectional view illustrating a method for manufacturing a wiring substrate according to an embodiment of the present invention;

FIG. 4B is a cross-sectional view illustrating the method for manufacturing a wiring substrate according to the embodiment of the present invention;

FIG. 4C is a cross-sectional view illustrating the method for manufacturing a wiring substrate according to the embodiment of the present invention;

FIG. 4D is a cross-sectional view illustrating the method for manufacturing a wiring substrate according to the embodiment of the present invention;

FIG. 4E is a cross-sectional view illustrating the method for manufacturing a wiring substrate according to the embodiment of the present invention;

FIG. 4F is a cross-sectional view illustrating the method for manufacturing a wiring substrate according to the embodiment of the present invention; and

FIG. 4G is a cross-sectional view illustrating the method for manufacturing the wiring substrate of the embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

A wiring substrate according to an embodiment of the present invention is described with reference to the drawings. The drawings to be referred to below are drawn with features according to an embodiment of the present invention emphasized for ease of understanding, without intending to show exact ratios of dimensions of structural elements.

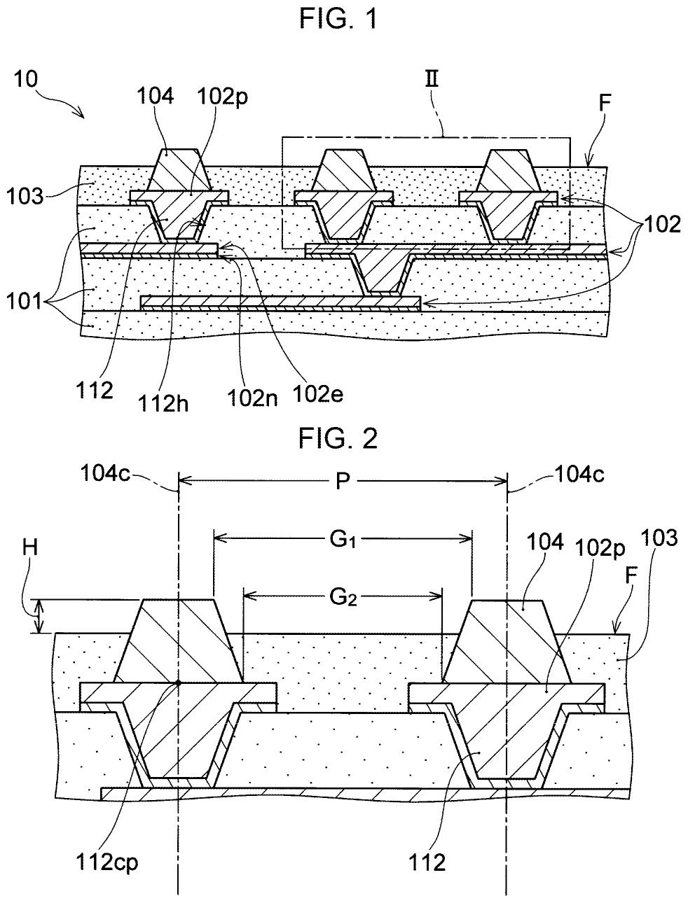

FIG. 1 partially illustrates a cross section of a wiring substrate 10, which is an example of the wiring substrate of the present embodiment. The wiring substrate 10 is formed of insulating layers and conductor layers, which are alternately laminated, and, among the insulating layers and conductor layers, resin insulating layers 101, a coating insulating layer 103 and conductor layers 102 are illustrated in FIG. 1. A surface (F) on one side of the wiring substrate 10 illustrated in FIG. 1 is formed as a component mounting surface on which an external electronic component such as a semiconductor element in a bare chip form or a passive element is mounted. The component mounting surface (F) of the wiring substrate 10 illustrated in FIG. 1 is formed of surfaces of the coating insulating layer 103 and metal posts 104 protruding from the coating insulating layer 103.

In the description of the wiring substrate 10 of the present embodiment, of each element of the wiring substrate 10, a component mounting surface (F) side, that is, an upper side on a drawing sheet is referred to as an “upper side” or simply “upper,” and an opposite side thereof is referred to as a “lower side” or simply “lower.” Therefore, an end part on the upper side of each element is also referred to as an “upper end” thereof, and an end part of the lower side of each element is also referred to as a “lower end” thereof. In FIG. 1, among the multiple resin insulating layers 101 and the multiple conductor layers 102 of the wiring substrate 10, three resin insulating layers 101 and three conductor layers 102 on the component mounting surface (F) side are illustrated. The number of the resin insulating layers 101 and the number of the conductor layers 102 of the wiring substrate 10 of the embodiment are not particularly limited and can be increased or decreased as appropriate. By including more conductor layers in the wiring substrate 10, a larger and more complicated electrical circuit can be formed in the wiring substrate 10 without increasing a planar size of the wiring substrate 10.

The conductor layers 102 in contact with the resin insulating layers 101 can have any conductor patterns. Each conductor layer 102 is electrically connected via via conductors 112, which are formed penetrating a resin insulating layer 101, to a conductor layer 102 on an opposite side of the resin insulating layer 101.

Among the three conductor layers 102 illustrated in FIG. 1, the conductor layer 102 formed closest to the component mounting surface (F) includes conductor pads (102p). The conductor pads (102p) are electrically connected via the metal posts 104 formed thereon to connection pads of an external electronic component such as a semiconductor element. The metal posts 104 protrude to the component mounting surface (F) side from the coating insulating layer 103, which is formed so as to cover surfaces of the conductor pads (102p) and the resin insulating layer 101.

The via conductors 112 each have a shape that is increased in diameter toward the component mounting surface (F) side. In the present embodiment, in particular, the via conductors 112 connected to the conductor pads (102p) are larger in diameter on the side connecting to the conductor pads (102p) than on the side (lower side) connecting to the conductor layer 102 on an opposite side. That is, the via conductors 112 are increased in diameter toward the conductor pads (102p). The term “increased in diameter” simply means that a longest distance between two points on an outer circumference of a horizontal cross section of each of the via conductors 112 is increased. Therefore, an opening shape of each of the via conductors 112 is not necessarily limited to a circular shape.

The metal posts 104 of the wiring substrate 10 that are connected to the conductor pads (102p) each have a shape that is increased in diameter in a direction opposite to that of the shape of each of the via conductors 112. In other words, the metal posts 104 are increased in diameter toward the conductor pads (102p). The diameter of the lower end (base end) side of the metal posts 104 connected to the conductor pads (102p) is larger than the diameter of the opposite side (component mounting surface (F) side).

In the example illustrated in FIG. 1, the via conductors 112, the conductor pads (102p), and the metal posts 104 are formed so as to have a positional relationship in which their central axes match each other. However, the relative positional relationship of the via conductors 112, the conductor pads (102p), and the metal posts 104 is not limited to this. For example, centers of the conductor pads (102p) and the metal posts 104 may shift in a predetermined direction with respect to centers of the via conductors 112. A physical resistance of structures formed of the via conductors 112, the conductor pads (102p) and the metal posts 104 against an external force from any direction may improve.

The resin insulating layers 101 of the wiring substrate 10 are each formed using any insulating resin such as an epoxy resin. A polyimide resin, a BT resin (bismaleimide-triazine resin), a polyphenylene ether resin, a phenol resin or the like can also be used. The resin insulating layers 101 may each contain inorganic filler such as silica. In the wiring substrate 10 in the example illustrated in FIG. 1, the resin insulating layers 101 do not each contain a core material. However, when necessary, the resin insulating layers 101 may each contain a core material such as a glass fiber or an aramid fiber. By containing a core material, the wiring substrate 10 can be improved in strength. The multiple resin insulating layers 101 may be respectively formed of different materials, or may all be formed of the same material.

The conductor layers 102 can each be formed using any material having suitable conductivity such as copper or nickel. The conductor layers 102 are each formed of, for example, a metal film layer (preferably an electroless copper plating film layer) or an electrolytic plating film layer (preferably an electrolytic copper plating film layer), or a combination thereof. In the example illustrated in FIG. 1, the conductor layers 102 are each formed to have a two-layer structure including a metal film layer (102n) and an electrolytic plating film layer (102e). However, the structure of each of the conductor layers 102 forming the wiring substrate 10 is not limited to the multilayer structure illustrated in FIG. 1. For example, the conductor layers 102 may be each formed to have a three-layer structure including a metal foil layer, a metal film layer, and an electrolytic plating film layer.

As illustrated in FIG. 1 the via conductors 112 can be integrally formed with the metal film layer (102n) and the electrolytic plating film layer (102e), which form the conductor layers 102. The via conductors 112 are so-called filled vias filling conduction holes (112h), and are formed of a metal film layer and an electrolytic plating film layer, which cover bottom surfaces and side surfaces in the conduction holes (112h). In particular, a conductor pad (102p) and a via conductor 112 that are connected to each other can be integrally formed by the mutually continuous metal film layer (102n) and electrolytic plating film layer (102e). An interface does not exist between the via conductor 112 and the conductor pad (102p) and a risk that a defect such as peeling may occur can be suppressed.

The coating insulating layer 103 can be formed using any insulating resin material. The coating insulating layer 103 is formed using, for example, a photosensitive polyimide resin or epoxy resin. The coating insulating layer 103 can be a solder resist layer. The coating insulating layer 103 covers portions of the conductor pads (102p) and portions of side surfaces of the metal posts 104 formed on the conductor pads (102p), and covers a surface of the resin insulating layer 101 exposed between the multiple conductor pads (102p). That is, the coating insulating layer 103 continuously covers the conductor pads (102p) and the metal posts 104 beyond a boundary portion corresponding to the connection surface between the conductor pads (102p) and the metal posts 104. Therefore, as compared to a case where the conductor pads (102p) and the metal posts 104 are covered with different separate insulating layers, a stress applied to a vicinity of a boundary portion between the conductor pads (102p) and the metal posts 104 can be effectively relaxed, and the risk that a defect such as peeling may occur can be suppressed.

The metal posts 104 are formed, for example, using copper or nickel. As will be described in detail later, the metal posts 104 can be formed by performing electrolytic plating of any metal material on the conductor pads (102p). When the metal posts 104 contains the same metal material as the metal contained in the conductor pads (102p), connectivity between the conductor pads (102p) and the metal posts 104 may be improved. For example, when the conductor pads (102p) are formed of an electroless copper plating film layer and an electrolytic copper plating film layer, the metal posts 104 are preferably also formed of an electrolytic copper plating film layer or an electroless copper plating film layer. A protective layer (not illustrated in the drawings) may be formed on upper ends of the metal posts 104. For example, a protective layer formed of Ni/Sn, Ni/Pd/Au, or the like is provided. A protective layer may be formed of Ni/Au or Sn. An OSP film may be formed.

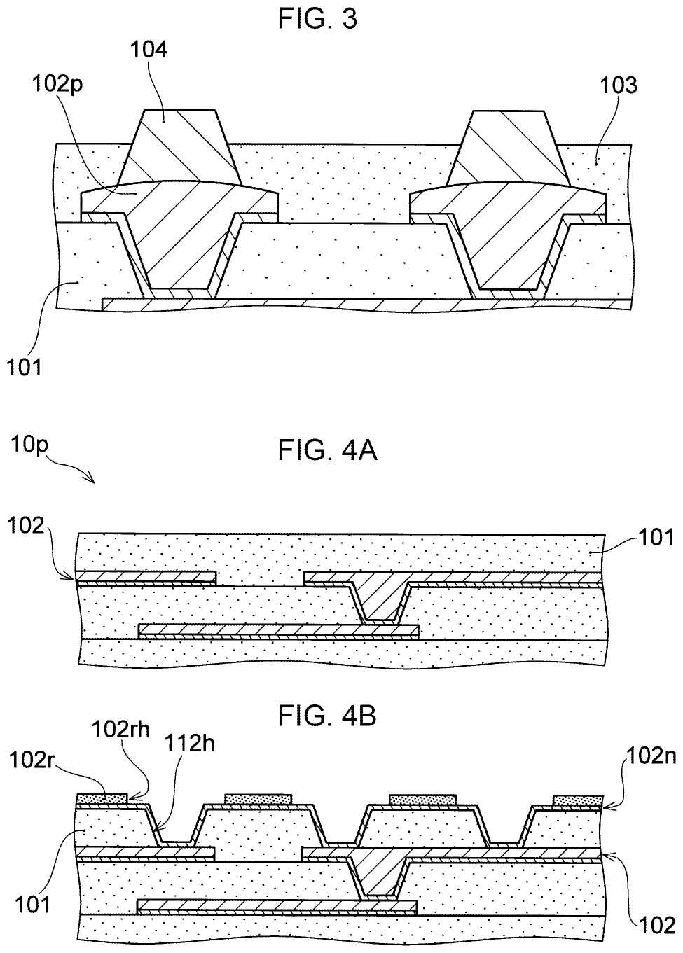

FIG. 2 is an enlarged view of a region (II) surrounded by a one-dot chain line in FIG. 1. A pair of adjacent metal posts 104 among the multiple metal posts 104 of the wiring substrate 10 are illustrated in FIG. 2. A distance (P) between central axes (104c) of the adjacent metal posts 104 corresponds to a pitch of connection pads of an electronic component that can be mounted on the component mounting surface (F) side of the wiring substrate 10. When the distance (P) is reduced in response to a demand for reducing the pitch of the connection pads of the electronic component, a gap between the adjacent metal posts 104 is also reduced. Therefore, there is a risk that connecting members that can be formed between upper end surfaces of the adjacent metal posts 104 and the connection pads of the electronic component may be excessively close to each other and an electrical short circuit may occur. The shape that the metal posts 104 are increased in diameter toward the conductor pads (102p) can suppress occurrence of such a defect.

Specifically, in the present embodiment, as illustrated in FIG. 2, since the multiple metal posts 104 are increased in diameter toward the conductor pads (102p) to which the metal posts 104 respectively connect, a gap (G1) on the upper end side between the adjacent metal posts 104 is larger than a gap (G2) on the base end side. Therefore, even when the distance (P) is small, occurrence of a defect such as a short circuit is suppressed on the upper end side of the metal posts 104, while a relatively large region for the connection to the conductor pads (102p) is provided and good connection to the conductor pads (102p) is realized on the base end side.

Further, in the present embodiment, in addition to that the metal posts 104 are increased in diameter toward the conductor pads (102p), the via conductors 112 are increased in diameter toward the conductor pads (102p) side. By having this structure, stress concentration at the connection surface between the metal posts 104 and the conductor pads (102p) can be relaxed. For example, a stress that can be applied to a vicinity of a connecting portion between the metal posts 104 and the conductor pads (102p) in a case such as when an electronic component is mounted on the component mounting surface (F) is likely to be effectively dispersed by the conductor pads (102p) and via conductors 112 having a integrate structure. The connection between the metal posts 104 and the conductor pads (102p) becomes even more reliable.

From a point of view of suppressing a short circuit of the metal posts 104 described above, the upper end side gap (G1) of the metal posts 104 preferably has a value of 20 μm or more. Further, a height (H) of a portion of each of the metal posts 104 that protrudes upward from the coating insulating layer 103 preferably has a value of 20 μm or more and 40 μm or less. Mounting of an electronic component on the metal posts 104 can be facilitated, and wet spread of connecting members formed on the upper end side of the metal posts 104 to adjacent metal posts 104 can be suppressed.

In the example illustrated in FIG. 2, points (112cp) that are on the upper surfaces of the conductor pads (102p) and correspond to centers of the via conductors 112 are connected to the metal posts 104. By having such a structure, rigidity of a structure having the via conductors 112, the conductor pads (102p) and the metal posts 104 as structural elements can be maintained, and the connection between the metal posts 104 and the conductor pads (102p) can be even more reliable.

From a point of view of suppressing a short circuit between adjacent metal posts 104 while obtaining a good connection between the metal posts 104 and the conductor pads (102p), a ratio of a surface area on the upper end side of the metal posts 104 to a surface area on the base end side connecting to the conductor pads (102p) is preferably 0.75 or more and 0.95 or less. The upper end surface area of the metal posts 104 is not excessively reduced, and connection reliability with connection pads of an electronic component or the like can be ensured.

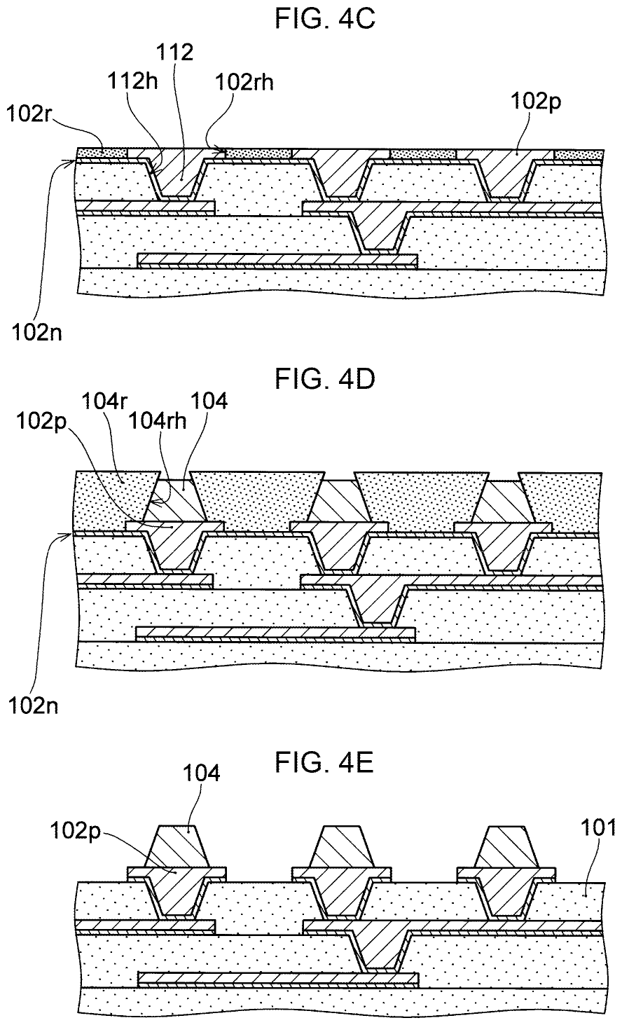

FIG. 3 illustrates an example in which a conductor pad (102p) has a structure different from that illustrated in FIG. 2. In the example illustrated in FIG. 3, a surface of the conductor pad (102p) on a side (upper side) connecting to a metal post 104 bulges toward the metal post 104. That is, the upper surface of the conductor pad (102p) is curved so as to be convex toward the metal post 104 side. When the surface of the conductor pad (102p) connecting to the metal post 104 is curved, a large connection area can be ensured, and the structure can have an even higher rigidity. Therefore, connection reliability between the conductor pad (102p) and the metal post 104 can be improved.

From a point of view of improving the connection reliability between the conductor pad (102p) and the metal post 104, it is preferable that an apex (point farthest from the resin insulating layer 101) of a bulging portion of the conductor pad (102p) (a point farthest from the resin insulating layer 101) is connected to the metal post 104. An upper surface of the metal post 104 may also bulge along with the bulging shape of the conductor pad (102p). Bondability with a connecting member such as a solder interposed between the metal post 104 and a connecting pad of an electronic component or the like may be improved. When the upper end surface of the metal post 104 bulges, connection reliability between the metal post 104 and a connection pad of an electronic component or the like can be improved.

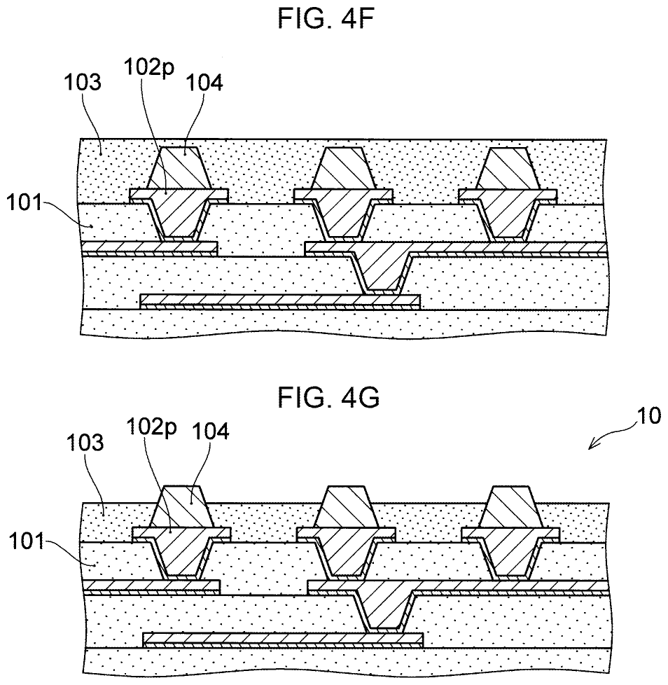

In the following, a method for manufacturing the wiring substrate 10 illustrated in FIG. 1 is described with reference to FIGS. 4A-4G. In FIGS. 4A-4G, similar to FIG. 1, the wiring substrate 10 is not entirely illustrated, and only a partial cross section of the component mounting surface (F) side where the metal posts 104 are formed is illustrated. Also in the following description, in each element, a side) on the component mounting surface (F) side of the wiring substrate 10 (an upper side in a drawing sheet) is referred to as “upper” or an “upper side,” and is also referred to as an “outer side” or simply “outer.”

First, as illustrated in FIG. 4A, a laminate (wiring substrate) (10p) in which processing up to the lamination of the outermost resin insulating layer 101 has been completed is prepared. The wiring substrate (lop) is manufactured using a general method for manufacturing a wiring substrate using a build-up method in which multiple insulating layers and multiple conductor layers are laminated.

Next, as illustrated in FIG. 4B, the conduction holes (112h) penetrating the outermost resin insulating layer 101 are formed at positions corresponding to formation locations of the via conductors 112 in the outermost resin insulating layer 101 of the wiring substrate (10p). The conduction holes (112h) are drilled by irradiation of laser such as CO₂ laser or YAG laser. The conduction holes (112h) formed in the outermost resin insulating layer 101 are formed to each have a shape that has a larger opening diameter on an upper side than on a lower side, that is, a shape that is increased in diameter from the lower side toward the upper side. The conduction holes (112h) having such a shape can be formed by irradiating a laser beam that is focused such that a spot diameter thereof is reduced toward a front end side. Then, the metal film layer (102n), which is, for example, an electroless copper plating film layer, is formed on inner sides of the conduction holes (112h) and over the entire surface of the resin insulating layer 101.

Subsequently, a plating resist (102r) for electrolytic plating is formed on the metal film layer (102n). The plating resist (102r) is formed using, for example, a dry film resist containing an acrylic resin or the like. The plating resist (102r) is formed to have openings (pad openings) (102rh) according to a conductor pattern including the conductor pads (102p) to be included in the outermost conductor layer 102 of the wiring substrate 10. The openings (102rh) can be formed using photolithography by exposure and development using a photomask having a suitable opening pattern.

Next, as illustrated in FIG. 4C, the conduction holes (112h) of the resin insulating layer 101 and the openings (102rh) of the plating resist (102r) are filled with a conductor by electrolytic plating using the metal film layer (102n) as a power feeding layer. The via conductors 112 and the conductor pads (102p) are formed. In the example illustrated in FIG. 4C, the upper surfaces of the conductor pads (102p) are formed flat. By appropriately adjusting conditions (such as temperature, current density, and plating time) of the electrolytic plating in which the metal film layer (102n) is used as a power feeding layer, the conductor pads (102p) that bulge upward can also be obtained. After the formation of the conductor pads (102p), the plating resist (102r) is removed.

Next, as illustrated in FIG. 4D, a resist layer (104r) for forming the metal posts 104 is formed on the metal film layer (102n) exposed by the removal of the plating resist (102r), and on the conductor pads (102p). The resist layer (104r) is formed using, for example, a photosensitive dry film resist containing an acrylic resin or the like. Openings (post openings) (104rh) for forming the metal posts 104 are formed in the resist layer (104r).

Similar to the formation of the opening (102rh) in the plating resist (102r) described above, photolithography can be used for the formation of the openings (104rh). By appropriately adjusting an opening shape of a photomask used in the photolithography, an exposure condition, and the like, the openings (104rh) each having a shape that is increased in diameter from an upper side toward a lower side are formed in the resist layer (104r). This shape of the openings (104rh) defines the shape of the metal posts 104 at a stage when the wiring substrate 10 is completed. By using photolithography in the formation of the pad openings (102rh) and the post openings (104rh), position adjustment of the pad openings (102rh) and the post openings (104rh) can be easily performed. In particular, position adjustment is easy when it is necessary to form the openings (104rh) such that the metal posts 104 are shifted in a predetermined direction with respect to the conductor pads (102p). Specifically, for example, first, a first alignment mark is used for adjusting the position of the photomask in the formation of the openings (102rh). Then, a second alignment mark at a position shifted from the first alignment mark in the predetermined direction is used for adjusting the position of the photomask in the formation of the openings (104rh). By simply adjusting the position of the photomask, the positions at which the openings (104rh) are formed can be easily shifted in the predetermined direction with respect to the conductor pads (102p).

Subsequently, the metal posts 104 are formed by performing electrolytic plating using the metal film layer (102n) as a power feeding layer on inner surfaces of the openings (104rh) of the resist layer (104r). The electrolytic plating used for the formation of the metal posts 104 is, for example, electrolytic copper plating or electrolytic nickel plating. A plating layer formed by the electrolytic plating grows in a so-called bottom-up manner upward from the surfaces of the conductor pads (102p), which are bottom surfaces of the openings (104rh).

The electrolytic plating is terminated in a state in which the openings (104rh) are filled to a desired position, and the formation of the metal posts 104 is completed. In this state, the upper end surface area of the metal posts 104 can have a ratio of 0.75 or more and 0.95 or less with respect to the surface area on the base end side (connection surface area with the conductor pads (102p)). The shape of the upper surface (upper end surface) of each metal post 104 can change depending on the shape of the surface of the conductor pad (102p) in contact with the metal post 104, a condition of the electrolytic plating, and the like. A surface protective film (not illustrated in the drawings) formed of Ni/Sn, Au, Ni/Au, Ni/Pd/Au, or the like can be formed on the upper end surface of each of the metal posts 104.

Next, as illustrated in FIG. 4E, the resist layer (104r) is removed. The metal film layer (102n) exposed by the removal of the resist layer (104r) is removed by etching. The conductor pads (102p) and the metal posts 104 are completely exposed, and the surface of the resin insulating layer 101 is exposed between the multiple conductor pads (102p).

Next, as illustrated in FIG. 4F, the coating insulating layer 103 is formed so as to cover the surface of the resin insulating layer 101 exposed between the multiple conductor pads (102p), and cover the conductor pads (102p) and the metal posts 104. The coating insulating layer 103 completely covers the conductor pads (102p) and the metal posts 104. As a result, the metal posts 104 are embedded in the coating insulating layer 103.

Next, as illustrated in FIG. 4G, a portion of the coating insulating layer 103 in the thickness direction is removed, and a portion of each of the metal posts 104 is exposed from the coating insulating layer 103. The metal posts 104 are in a state of protruding upward from the coating insulating layer 103. For the partial removal of the coating insulating layer 103 in the thickness direction, for example, a dry process such as plasma etching using CF₄ or CF₄+O₂ can be used. Further, it is also possible that the coating insulating layer 103 is partially removed in the thickness direction by a blast treatment to expose the metal posts 104. Through the above processes, the wiring substrate 10 illustrated in FIG. 1 is completed. A surface protective film (not illustrated in the drawings) formed of heat-resistant preflux or the like may be formed on portions of the metal posts 104 exposed from the coating insulating layer 103.

In the manufacture of the wiring substrate 10 of the embodiment, after the removal of the plating resist (102r) following the formation of the conductor pads (102p) illustrated in FIG. 4C, the wiring substrate 10 may be manufactured through processes different from the above-described processes. For example, the resist layer (104r) is not formed on the metal film layer (102n), and, following the removal of the plating resist (102r), the metal film layer (102n) exposed between the conductor pads (102p) is also removed. The coating insulating layer 103 is formed on the surface of the resin insulating layer 101 exposed by the removal of the metal film layer (102n), and on the conductor pads (102p).

For example, the coating insulating layer 103 as a solder resist covers the surface of the resin insulating layer 101 and covers the conductor pads (102p). Then, openings exposing the conductor pads (102p) are formed in the coating insulating layer 103 by exposure and development. In this case, similar to the case where the openings (104rh) are formed in the resist layer (104r), openings each having a shape that has a larger opening diameter on a lower side than on an upper side are formed. Next, the metal posts 104 are formed by electroless plating in the openings formed in the coating insulating layer 103. In this case, in the formation of the metal posts 104, a catalyst layer for plating deposition can be formed in the openings prior to electroless plating. For the catalyst layer, for example, a metal such as palladium (Pd), gold (Au), platinum (Pt), or ruthenium (Ru) can be used. An electroless plating layer is formed only in the openings, and the metal posts 104 that are each increased in diameter from the upper end side toward the base end side are formed. Following the formation of the metal posts 104, a portion of the coating insulating layer 103 in the thickness direction is removed. The metal posts 104 are partially exposed from the coating insulating layer 103 and protrude upward. The formation of the wiring substrate 10 is completed.

The wiring substrate of the embodiment is not limited to a wiring substrate having the structures exemplified in the drawings, or the structures or materials exemplified in the present specification. For example, the conductor layer 102 closest to the component mounting surface (F) may include different conductor patterns in addition to the conductor pads (102p). Further, the method for manufacturing the wiring substrate of the embodiment is not limited to the method described with reference to the drawings, and conditions, processing order, and the like of the method can be modified as appropriate. Depending on a structure of an actually manufactured wiring substrate, some of the processes may be omitted, or other processes may be added.

In the wiring substrate of Japanese Patent Application Laid-Open Publication No. 2010-129996, a region on a lower end side of the metal post where the metal post and the connection pad connect to each other is smaller than an upper end surface area of the metal post. Therefore, it is thought that, when the metal post is formed relatively small, a connection region between the metal post and the connection pad is relatively small, making it difficult to obtain a good connection. It is thought that there is a risk that a connection failure due to peeling or the like at a connection surface between the metal post and the connection pad may occur.

A wiring substrate according to an embodiment of the present invention includes: a resin insulating layer; a via conductor that penetrates the resin insulating layer; a conductor pad that is formed on the resin insulating layer and is connected to the via conductor; a coating insulating layer that covers the resin insulating layer and the conductor pad; and a metal post that is formed on the conductor pad and protrudes from the coating insulating layer. The via conductor is increased in diameter toward the conductor pad, and the metal post is increased in diameter toward the conductor pad.

A method for manufacturing a wiring substrate according to an embodiment of the present invention includes: preparing a laminate in which a resin insulating layer is laminated on a conductor layer, and forming a conduction hole in the resin insulating layer, the conduction hole having a shape that is increased in diameter from a lower side toward an upper side; forming a plating resist on the resin insulating layer, and forming a pad opening in the plating resist; forming a via conductor by filling the conduction hole with a conductor, and forming a conductor pad by filling the pad opening with a conductor; forming a resist layer on the conductor pad, and forming a post opening in the resist layer, the post opening having a shape that is increased in diameter from an upper side toward a lower side; and forming a metal post by filling the post opening with a conductor. The pad opening and the post opening are formed by photolithography.

According to an embodiment of the present invention, a good connection structure between a metal post and a conductor pad can be provided. A highly reliable wiring substrate in which occurrence of a defect such as peeling is suppressed can be provided.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring substrate, comprising:
a resin insulating layer;
a via conductor formed in the resin insulating layer such that the via conductor is penetrating through the resin insulating layer;
a conductor pad formed on the resin insulating layer and connected to the via conductor;
a coating insulating layer is formed on the resin insulating layer such that the coating insulating layer is covering the conductor pad; and
a metal post formed on the conductor pad and protruding from the coating insulating layer,
wherein the via conductor is formed such that the via conductor is increased in diameter toward the conductor pad, and the metal post is formed such that the metal post is increased in diameter toward the conductor pad.

2. The wiring substrate according to claim 1, further comprising:
a second via conductor formed in the resin insulating layer such that the second via conductor is penetrating through the resin insulating layer;
a second conductor pad formed on the resin insulating layer and connected to the second via conductor; and
a second metal post formed on the second conductor pad and protruding from the coating insulating layer,
wherein the second via conductor is formed such that the second via conductor is increased in diameter toward the second conductor pad, and the second metal post is formed such that the second metal post is increased in diameter toward the second conductor pad.

3. The wiring substrate according to claim 2, wherein the second metal post is positioned adjacent to the metal post such that a gap between upper ends of the metal post and second metal post is larger than a gap between base ends of the metal post and second metal post.

4. The wiring substrate according to claim 1, wherein the metal post is formed such that a ratio of a surface area on an upper end of the metal post to a surface area on a base end of the metal post connecting to the conductor pad is in a range of 0.75 to 0.95.

5. The wiring substrate according to claim 1, wherein the conductor pad and the metal post comprise a same metal material.

6. The wiring substrate according to claim 1, wherein the conductor pad and the via conductor are integrally formed.

7. The wiring substrate according to claim 1, wherein the coating insulating layer is formed such that the coating insulating layer is continuously covering the conductor pad and a portion of a side surface of the metal post.

8. The wiring substrate according to claim 2, wherein the metal post is formed such that a ratio of a surface area on an upper end of the metal post to a surface area on a base end of the metal post connecting to the conductor pad is in a range of 0.75 to 0.95, and the second metal post is formed such that a ratio of a surface area on an upper end of the second metal post to a surface area on a base end of the second metal post connecting to the second conductor pad is in a range of 0.75 to 0.95.

9. The wiring substrate according to claim 2, wherein the conductor pad and the metal post comprise a same metal material, and the second conductor pad and the second metal post comprise a same metal material.

10. The wiring substrate according to claim 2, wherein the conductor pad and the via conductor are integrally formed, and the second conductor pad and the second via conductor are integrally formed.

11. The wiring substrate according to claim 2, wherein the coating insulating layer is formed such that the coating insulating layer is continuously covering the conductor pad, the second conductor pad, and portions of side surfaces of the metal post and second metal post.

12. The wiring substrate according to claim 4, wherein the conductor pad and the metal post comprise a same metal material.

13. The wiring substrate according to claim 4, wherein the conductor pad and the via conductor are integrally formed.

14. The wiring substrate according to claim 4, wherein the coating insulating layer is formed such that the coating insulating layer is continuously covering the conductor pad and a portion of a side surface of the metal post.

15. The wiring substrate according to claim 5, wherein the conductor pad and the via conductor are integrally formed.

16. The wiring substrate according to claim 5, wherein the coating insulating layer is formed such that the coating insulating layer is continuously covering the conductor pad and a portion of a side surface of the metal post.

17. The wiring substrate according to claim 6, wherein the coating insulating layer is formed such that the coating insulating layer is continuously covering the conductor pad and a portion of a side surface of the metal post.

18. The wiring substrate according to claim 8, wherein the conductor pad and the metal post comprise a same metal material, and the second conductor pad and the second metal post comprise a same metal material.

19. A method for manufacturing a wiring substrate, comprising:
preparing a laminate comprising a conductor layer and a resin insulating layer laminated on the conductor layer;
forming a hole in the resin insulating layer such that the hole is connected to the conductor layer and is increased in diameter from a lower side at the conductor layer toward an upper side of the hole;
forming a plating resist on the resin insulating layer such that the plating resist has a pad opening connected to the hole;
filling the hole and the pad opening with a conductor such that a via conductor is formed in the hole and that a conductor pad is formed in the pad opening;
forming a resist layer on the conductor pad such that the resist layer has a post opening connected to the conductor pad and that the post opening is increased in diameter from an upper side toward a lower side of the post opening at the conductor pad; and
filling the post opening with a conductor such that a metal post is formed in the post opening.

20. The method of claim 19, wherein the pad opening and the post opening are formed by photolithography.
